(19) United States
(12) Patent Application Publication
(10) Pub. No.: US 2025/0089214 A1
(43) Pub. Date: Mar. 13, 2025

(54) THERMAL CONTROL DEVICE, IN PARTICULAR FOR A MOTOR VEHICLE, AND ASSOCIATED THERMAL CONTROL UNIT

(71) Applicant: VALEO SYSTEMES THERMIQUES, La Verriere (FR)

(72) Inventors: Moussa NACER BEY, La Verriere (FR); Kamel AZZOUZ, La Verriere (FR); Julien TISSOT, La Verriere (FR); Sergio DA COSTA PITO, La Verriere (FR); Guillaume GARDERE, La Verriere (FR)

(73) Assignee: VALEO SYSTEMES THERMIQUES, La Verriere (FR)

(21) Appl. No.: 18/728,495

(22) PCT Filed: Jan. 12, 2023
(86) PCT No.: PCT/EP2023/050648

§ 371 Date: Jul. 12, 2024

(30) Foreign Application Priority Data
Jan. 14, 2022 (FR) FR2200320

(51) Int. Cl. H05K 7/20; H01M 10/6567

(52) U.S. Cl. CPC H05K 7/20345; H01M 10/6567; H01M 2220/20

(57) ABSTRACT

The invention relates to a device for thermal regulation of a predefined number of electronic and/or electric components, in particular for a motor vehicle, the device including: a dielectric fluid circuit including at least one supply line, a predefined number of dielectric fluid spraying nozzles fluidically connected to the supply line and configured to be placed so as to wet at least one surface of the at least one component, and at least one dielectric fluid collector configured to be placed so as to collect the dielectric fluid after the spraying operation, the collector having at least one separating rib configured to extend between at least two components. The invention also relates to a thermal regulation unit including such a device.

### TECHNICAL FIELD

The present invention relates to a device for thermal regulation of electric and/or electronic components liable to release heat during operation, in particular in the automotive field. The invention also relates to a thermal regulation unit comprising such a device.

### BACKGROUND OF THE INVENTION

The components likely to be covered by the present invention can be electrical energy storage elements, in particular battery elements, or power electronics elements, for example, but non-limitingly, semiconductors such as diodes or transistors. They could also be components of computer servers.

The invention is advantageously applicable in the field of devices for thermal regulation of a power electronics device or module, which is to say a device or module having power electronics components. During operation, the temperature of such a power electronics device or module can rise, running the risk of damage to some of the power electronics components.

The invention is also advantageously applicable in the field of devices for thermal regulation of an electrical energy storage device, such as a battery unit or battery pack for an electric and/or hybrid motor vehicle. The electrical energy for electric and/or hybrid vehicles is supplied by one or more batteries. During operation, the electrical energy storage elements, such as the batteries, are made to heat up and thus run the risk of being damaged. In particular, one charging technique, referred to as rapid charging, consists in charging the energy storage elements at a high voltage and high amperage for a short time, in particular for a maximum time of about twenty minutes. Such rapid charging causes the electrical energy storage elements to heat up significantly, which must be managed.

In the field of motor vehicles, it is known practice to use a device for thermal regulation, in particular for the cooling, of components, for example electrical energy storage components, such as batteries. Such a thermal regulation device makes it possible to modify a temperature of an electrical energy storage device, for example when the vehicle is being started in cold weather by increasing its temperature for example, or when traveling or during a recharging operation of said system by decreasing the temperature of the battery elements, which tend to heat up when they are being used.

According to one known solution, the thermal regulation device has a cold plate inside which a coolant fluid circulates and which is arranged in contact with the components to be cooled. It has been found that such an arrangement can lead to non-uniform cooling of the components of the same device, for example electrical energy storage device, that is to be cooled, which then causes a decrease in the overall performance. Such a thermal regulation device also has high thermal resistance because of the thicknesses of material present between the coolant fluid and the components to be cooled. Furthermore, this solution generally takes up considerable space.

According to another known thermal regulation solution, in particular cooling solution, for components such as battery elements, a dielectric fluid is projected, generally in the form of a spray, directly onto the components via a dielectric fluid circuit and orifices or nozzles for spraying dielectric fluid. A heat exchange can then take place between the components and the dielectric fluid that comes into direct contact with a surface of the components.

After the dielectric fluid has been sprayed on the components, in particular in the liquid phase, the dielectric fluid can flow along the components, and accumulate in particular in a bottom part of the housing that receives the electric and/or electronic components to be thermally regulated.

However, in particular in the context of use in a vehicle, it can be the case that the components are not necessarily laid flat, parallel to the horizontal, but they can be inclined, tilted in relation to the horizontal, such that the dielectric fluid can only accumulate on one side. The dielectric fluid accumulated is then not distributed uniformly in relation to the components. These problems can also arise when the vehicle is itself inclined, for example on a road with a gradient, or owing to vibrations caused by the state of the road, driving, or any other condition. In addition, this can cause a pump to work harder, for example to be able to draw the dielectric fluid that has accumulated on one side out of the housing. Moreover, the pump would run the risk of drawing in air, and this could damage it.

### SUMMARY OF THE INVENTION

An objective of the present invention is to at least partially overcome one or more of the aforementioned drawbacks by proposing a thermal regulation unit for avoiding unbalanced accumulation of dielectric fluid and also for making the thermal regulation, such as the cooling, of the components more uniform irrespective of the installation of the device to be regulated, in particular even when the components are tilted or when the vehicle moves and is inclined to a considerable extent.

To this end, the invention relates to a thermal regulation device for a predefined number of electronic and/or electric components, in particular for a motor vehicle. Said device comprises:
a dielectric fluid circuit comprising at least one supply line, and
a predefined number of dielectric fluid spraying nozzles fluidically connected to said supply line and configured to be placed so as to wet at least one surface of said at least one component.

According to the invention, said device comprises at least one dielectric fluid collector configured to be placed so as to collect the dielectric fluid after the spraying operation. Said collector has at least one separating rib configured to extend between at least two components.

Such a collector makes it possible to improve the collection of the dielectric fluid that has been sprayed. This collection can be done in particular in a lower part before the fluid is discharged.

The thermal regulation device can also have one or more of the following features described below, considered separately or in combination.

With preference, said at least one separating rib is configured to define at least two distinct dielectric fluid collecting compartments on either side of said rib.

The or at least one rib between two components that makes it possible to delimit dielectric fluid collecting compartments avoids the sprayed dielectric fluid accumulating only on one side. As a result, irrespective of the inclination of the vehicle for example, the rib makes it possible to ensure uniform collection of the dielectric fluid and the dielectric fluid collected in each compartment can then be discharged, for example by being drawn in by a pump.

Such a rib can also have a function of holding the components or modules in position.

According to one embodiment, said collector extends mainly along a longitudinal axis.

Said at least one rib can extend along an axis transverse to the longitudinal axis.

Said at least one rib is, for example, configured to extend parallel to two facing lateral faces of said at least two components.

According to one embodiment, said collector has at least two ribs.

The ribs can be spaced by a predefined interval. This interval can be constant or non-constant.

Said collector can have a plurality of ribs spaced by a predefined interval and configured to extend between each pair of components.

Said collector is, for example, situated opposite said supply line.

Said collector can be fluidically connected to at least one dielectric fluid outlet port so as to make it possible to discharge the dielectric fluid from said device.

According to another aspect, said collector comprises a predefined number of dielectric fluid discharging orifices.

Said device can comprise at least one discharge line into which the predefined number of discharging orifices of said collector lead. Said outlet port can lead into this discharge line.

Advantageously, said collector has at least one slope inclined in relation to the horizontal and descending toward at least one discharging orifice.

The slope can form a non-zero angle of inclination in relation to the horizontal. The angle of inclination is less than 90°, for example is around 45°.

The descending slope extends, for example, from said or at least one rib to said at least one discharging orifice.

Said collector can have at least two descending slopes extending on either side of a rib or said rib toward a respective discharging orifice.

The slopes can be identical or different.

The collector can have one or more portions of frustoconical overall shape.

According to yet another aspect, at least one of the following elements: said supply line, said collector and said rib, can be made from a composite plastics material.

Said material is advantageously heat-resistant.

The invention also relates to a thermal regulation unit. This unit can be intended to be fitted to a vehicle, in particular a motor vehicle.

The regulation unit comprises a predefined number of electronic and/or electric components, in particular electrical storage components.

The thermal regulation unit also comprises at least one thermal regulation device as described above, comprising:
a dielectric fluid circuit comprising at least one supply line,
a predefined number of dielectric fluid spraying nozzles fluidically connected to said supply line and placed so as to wet at least one surface of at least one component, and
at least one dielectric fluid collector placed so as to collect the dielectric fluid after the spraying operation, said collector having at least one separating rib extending between at least two components.

The regulation unit can in particular have a housing that receives the predefined number of electronic and/or electric components.

Said supply line and said collector can be placed in the housing on either side of said at least two components.

Said supply line is, for example, placed in a first part, or upper part, of the housing.

Said collector is, for example, placed in a second part, or bottom part, of the housing.

The housing can have a cover that closes the housing, and a bottom wall situated opposite the cover.

Said at least one supply line is, for example, placed between said components and the cover.

Said collector is, for example, placed between said components and the bottom wall.

According to one embodiment, said rib can extend along an axis substantially perpendicular to the bottom wall of the housing.

The rib is advantageously continuous. It can extend over the entire length or the entire width of a component.

Said collector can have at least one slope which is inclined in relation to the bottom wall of the housing and descends toward at least one discharging orifice of said collector.

The bottom wall of the housing extends, for example, horizontally, parallel to the horizontal.

Furthermore, at least one of the following elements: said supply line and said collector, can be made by overmolding over an element of the casing.

At least one discharge line can be formed between said collector and the housing, more specifically a wall of the housing, such as the bottom wall, positioned facing said at least one discharging orifice.

The invention can also relate to a battery pack comprising a plurality of energy storage cells and at least one thermal regulation device as defined above, comprising a dielectric fluid circuit and a predefined number of dielectric fluid spraying nozzles placed so as to wet the plurality of energy storage cells.

### BRIEF DESCRIPTION OF DRAWINGS

Further advantages and features of the invention will become more clearly apparent on reading the following description, which is given by way of illustrative and non-limiting example, and the appended drawings, in which:

FIG. 1 schematically illustrates a thermal regulation unit comprising components or modules that are to be thermally regulated and are received in a housing closed by a cover, and a thermal regulation device comprising a dielectric fluid collector according to a first embodiment.

FIG. 2 is a bottom view of the collector of FIG. 1.

FIG. 3 is a bottom view of the unit of FIG. 1.

FIG. 4 schematically illustrates a thermal regulation unit comprising components or modules that are to be thermally regulated and a thermal regulation device comprising a dielectric fluid collector according to a second embodiment.

### DETAILED DESCRIPTION OF THE INVENTION

In these figures, elements that are identical have the same reference numbers.

The following embodiments are examples. Although the description refers to one or more embodiments, this does not necessarily mean that each reference relates to the same embodiment, or that the features apply only to one embodiment. Individual features of different embodiments can also be combined or interchanged in order to create other embodiments.

In the description, certain elements can be indexed, for example first element or second element. In this case, this is simply indexing to differentiate and designate elements that are similar but not identical. This indexing does not imply priority being given to one element over another and such designations can be interchanged easily without departing from the scope of the present invention. This indexing also does not imply any chronological order.

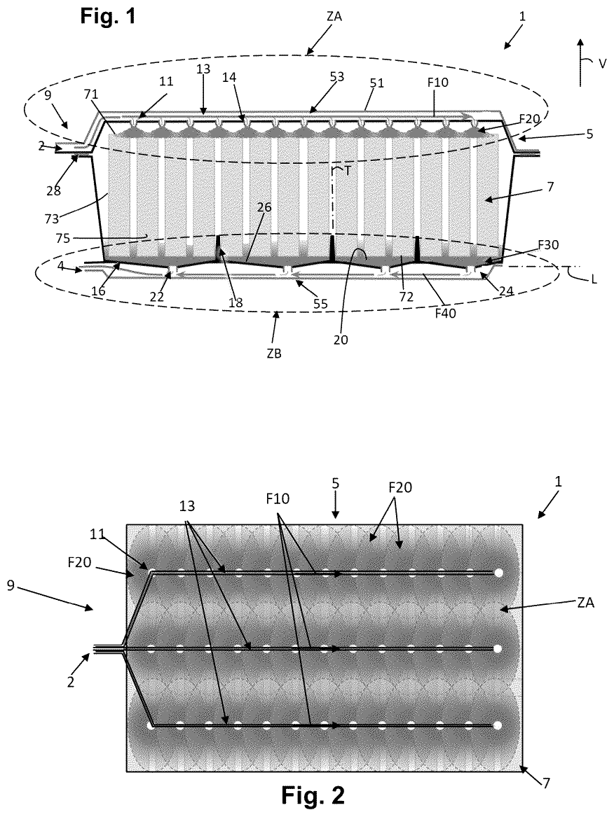

FIG. 1 schematically shows a thermal regulation unit 1 which can be intended to be fitted to a vehicle, in particular a motor vehicle.

The thermal regulation unit 1 comprises at least one thermal regulation device 3, which is described in more detail below. Such a thermal regulation device 3 in particular comprises at least one inlet port 2 configured to introduce the dielectric fluid into the thermal regulation device 3 and a dielectric fluid outlet port 4 configured to discharge the dielectric fluid out of the thermal regulation device 3.

The thermal regulation unit 1 can also comprise a device 5 to be thermally regulated, such as an electrical storage device 5, having one or more electric or electronic components of which the temperature must be regulated, for example reduced.

The device 5 can comprise one or more modules 7, in particular for electrical storage, having the one or more electronic and/or electric components. The thermal regulation device 3 can regulate the temperature of the one or more modules 7, in particular by spraying the dielectric fluid.

By way of non-limiting example, the thermal regulation unit 1 can be a battery pack comprising a plurality of energy storage cells, the temperature of which is regulated by the thermal regulation device 3.

In the present case, a module 7 can be an energy storage cell. In a variant, one module 7 can comprise multiple energy storage cells. A module 7 can also be defined as a container or housing comprising one or more electronic and/or electric components.

The device 5, in particular electrical storage device, can comprise a housing 51 which is partially illustrated schematically and is intended to receive the one or more components or modules 7.

One or more elements of the thermal regulation device 3, which is described in detail below, can be integrated in the housing 51, for example by overmolding.

The inlet port 2 and the outlet port 4 for the dielectric fluid can be formed in the housing 51.

The housing 51 can for example have a parallelepipedal overall shape.

It is intended to be closed by a cover 53. The housing 51 has a bottom wall 55 situated opposite the cover 53 when the housing 51 is closed. The bottom wall 55 of the housing 51 extends horizontally, in other words parallel or substantially parallel to the horizontal.

The housing 51 comprises lateral walls connected by the bottom wall 55. The walls of the housing 51 delimit an internal volume of the housing which receives the components or modules 7.

The components or modules 7 can be positioned in a row or in multiple rows within the internal volume of the housing 51. These rows are advantageously positioned parallel to one another.

Furthermore, the components or modules 7 are schematically shown with a parallelepipedal overall shape. This parallelepipedal shape has a length, a width and a height. The components or modules 7 each have an upper face 71 and an lower face 72, which are situated opposite one another and connected by lateral faces 73, 75. The upper face 71 can be intended to be placed facing the cover 53 of the housing 51 that receives the one or more components or modules 7. The lower face 72 is intended to be placed against a bottom of the housing 51. The oppositely situated upper face 71 and lower face 72 extend in the length and width directions of a component or module 7. Two first lateral faces 73 are for example two oppositely situated large lateral faces extending in the length and height direction of the component or module 7. Two second lateral faces 75 are for example two oppositely situated small lateral faces extending in the width and height direction of the component or module 7. Any other shape can be envisaged for the components or modules 7.

One or more surfaces of a component or module 7 are intended to be wetted by the dielectric fluid.

The one or more surfaces of a component or module 7 that are intended to be wetted by the dielectric fluid can be flat or substantially flat.

In a variant, a surface intended to be wetted, such as the surface of an upper face 71 of a component or module 7, can be curved or convex, with a convexity toward the outside of the component or module 7. The curvature of this surface to be wetted makes it easier for the dielectric fluid to flow toward the surfaces of the lateral faces 73, 75 of the component or module 7 which extend vertically with reference to the example of FIG. 1.

To this end, it is also conceivable for the surface intended to be wetted to be inclined in relation to a horizontal or vertical plane with reference to the orientation of the thermal regulation unit 1 after final assembly. By way of example, for a surface to be wetted on the upper face 71 of a component or module 7, this surface can be inclined in relation to the horizontal plane or to the plane defined by the oppositely situated lower face of the component or module 7, and in this case the upper face 71 is not strictly perpendicular to the lateral faces 73, 75 of the component or module 7. For a surface to be wetted of a lateral face 73, 75 of a component or module 7, this surface can be inclined in relation to the vertical plane, and in this case the lateral face 73, 75 is not strictly perpendicular to the upper face 71 and lower face of the component or module 7.

In addition, the unit 1 can have at least one dielectric fluid spraying zone ZA and at least one collecting zone ZB for collecting the dielectric fluid after the spraying operation, in particular before it is discharged from the unit 1.

The spraying zone ZA and the collection zone ZB are in particular provided on either side of the components or modules 7 to be thermally regulated.

In particular, the spraying zone ZA can be defined in a first part of the housing 51 and the collection zone ZB can be defined in a second part of the housing 51. These two parts are, for example, situated opposite one another. With reference to the orientation of the elements in FIG. 1, the first part is an upper or top part of the housing 51 and the second part is a lower or bottom part of the housing 51. The terms top and bottom are defined with respect to a vertical axis V of the thermal regulation unit 1.

The invention relates in particular to the thermal regulation device 3 that is described in more detail below. It comprises in particular a dielectric fluid circuit 9, a predefined number of dielectric fluid spraying nozzles 11 and at least one dielectric fluid collector 16.

### Dielectric Fluid Circuit

The dielectric fluid circuit 9 can possibly comprise at least one dielectric fluid circulating member (not shown), such as a pump. The flow of the dielectric fluid in the circuit 9 can be controlled via this member, such as a pump. A dielectric fluid storage tank can also be provided. The circulation of the dielectric fluid before the spraying operation is schematically shown by arrows F10.

The dielectric fluid can be single-phase. Once it has been sprayed, in particular in the liquid phase, the dielectric fluid can be drawn back in by a pump, for example. The dielectric fluid drawn back in can optionally be conveyed to an exchanger (not shown) for cooling before being reintroduced into the dielectric fluid circuit 9 for the thermal regulation of the components or modules 7.

The dielectric fluid circuit 9 can comprise one or more lines 13, in particular for supplying dielectric fluid to the one or more nozzles 11. Such lines form supply lines 13.

The one or more supply lines 13 lead into the inlet port 2.

A supply line 13 can fluidically connect multiple nozzles 11. In other words, it is designed to direct the dielectric fluid to each of the nozzles 11.

According to a particular embodiment, which is not shown, a supply line 13 can be produced by joining two half-shells delimiting an internal channel for supplying the nozzles 11. At least one or both half-shells can be made from a plastics material. The two half-shells can possibly be joined by overmolding, adhesive bonding or ultrasonic welding.

In addition, the dielectric fluid circuit 9 and more specifically the or at least one of the supply lines 13 can have one or more distribution or connection points 14 for the nozzles 11. A single nozzle 11 can be connected to a distribution or connection point 14. In a variant or in addition, at least two nozzles 11 can be connected to a common distribution or connection point 14.

The dielectric fluid circuit 9 can have multiple supply lines 13, which are in particular parallel, each making it possible to distribute the dielectric fluid to the nozzles 11 or to respective series of nozzles 11. In the example illustrated in FIG. 2, the dielectric fluid circuit 9 comprises three supply lines 13 configured to convey the dielectric fluid toward the respective series of spraying nozzles 11. The number of supply lines 13 is in no way limiting and can be modified and adapted as required.

In a variant, a common supply line 13 can be provided to supply multiple nozzles, or even all of the nozzles 11, in series.

As a result, during operation, the dielectric fluid is distributed into one or more supply lines 13 so as to supply the various nozzles 11. The dielectric fluid can then be projected by the nozzles 11 so as to come into contact with the surfaces to be wetted of the components or modules 7.

Furthermore, with reference again to FIG. 1, the supply line or at least one of the supply lines 13 can be placed so as to extend at least partially facing a row, or between two rows, of components or modules 7, in particular above a row, or the spacing between two rows, of components or modules 7. The supply line 13 can thus be interposed between the components or modules 7 and the cover 53 of the housing 51 that receives the components or modules 7.

The circuit 9, and in particular the one or more supply lines 13, can possibly be fixed to a support, for example extending from a wall or the cover 53 of the housing 51. In an alternative, the circuit 9 can have integrated supports configured to be fixed to a wall or the cover of the housing 51.

Advantageously, the circuit 9, and in particular the one or more supply lines 13, can be integrated in the housing 51, in particular in the cover 53 of the housing 51, for example by overmolding. This can be done in particular with one or more supply lines 13 in a composite plastics material, which is in particular heat-resistant.

In addition, the or at least one supply line 13 and the or at least one collector 16, described in detail below, are advantageously placed in the housing 51 on either side of the components or modules 7. In the example illustrated, the or at least one supply line 13 is placed in the first part, or upper part, of the housing 51 and the collector 16 is placed in the oppositely situated second part, or lower part, of the housing 51.

### Dielectric Fluid Spraying Nozzles

As regards the nozzles 11, how many there are can be defined on the basis of the flow rate of the dielectric fluid or the length of the dielectric fluid circuit 9.

The nozzles 11 are intended to be placed so as to wet at least one surface of at least one component or module 7, for example energy storage component or module, with dielectric fluid. A surface to be wetted of a component or module 7 can be an upper surface, which is to say one intended to be placed facing the cover 53 of the housing 51. In a variant or in addition, it can be a lateral surface of the component or module 7. The surface to be wetted can be a flat or substantially flat surface, or conversely a surface which is curved or at least partially curved.

The nozzles 11 are in particular intended to be placed in the spraying zone ZA of the unit 1, more specifically defined in the first part, or top part, of the housing 51.

The nozzles 11 each comprise one or more dielectric fluid projecting orifices. The projecting orifices can optionally be formed by spraying slots.

The projecting orifices can have an ovoid overall shape or contour. In a variant, the projecting orifices can have a circular overall shape or contour.

The nozzles 11 are in particular designed so as to project at least one jet of dielectric fluid F20.

Such a jet of dielectric fluid has, for example, a conical overall shape. The contour of the projecting orifices of such nozzles 11 has, for example, a circular overall shape.

According to another alternative, at least one nozzle 11 is in particular designed so as to project at least one fan-shaped jet of dielectric fluid. More specifically, the shape is that of an open fan defining a circular sector or even a semicircle. The circular sector is delimited by two radii and a circular arc. The tip of the circular sector is defined by the nozzle 11. Such a jet has a flat overall shape or the shape of a cone which is flattened, which is to say inscribed between two main directions. These two directions are not parallel to one another, but intersect. More specifically, the radii defining the circular sector each extend along one of these two directions. These directions intersect at the tip of the circular sector.

The jet of dielectric fluid F20 of flat overall shape defines, for example, an opening angle greater than 90°, in particular between 100° and 180°, preferably of around 170°. This angle can be adapted so that it uniformly covers an entire surface to be wetted of at least one component or module 7.

For example, at least some nozzles 11 can have a single projecting orifice so as to project a single jet of dielectric fluid F20.

In a variant or in addition, at least some nozzles 11 can have at least two projecting orifices so as to project at least two jets of dielectric fluid F20. Such nozzles 11 with a plurality of orifices are also referred to as multi-jet nozzles 11.

The various jets of dielectric fluid F20 intended to be projected by a multi-jet nozzle 11 can be similar or different. They can have the same extent or different extents. At least some jets of dielectric fluid, for example of flat overall shape, can be projected with the same opening angle or with different opening angles. At least some jets, for example of flat overall shape, can be projected in parallel planes or in intersecting planes. At least some jets of dielectric fluid, for example of conical overall shape, can have different diameters. At least some jets can be intended to wet the same surface of a component or module 7, or conversely different surfaces, of one or more components or modules 7.

Furthermore, various placement strategies for the nozzles 11 are conceivable.

One or more nozzles 11 can be intended to be arranged between at least two components or modules 7.

More specifically, the one or more nozzles 11 can be placed facing a gap between two adjacent components or modules 7, and in particular above a gap between the upper faces 71 of two adjacent components or modules 7. On final assembly of the thermal regulation unit 1, such nozzles 11 above the space between the upper faces 71 of two adjacent components or modules 7 are then interposed between the cover 53 of the housing 51 and the components or modules 7 received in the housing 51.

At least one such nozzle 11 can be positioned at every second gap between modules for example, or at each gap between modules.

The nozzles 11 can be placed centrally or substantially centrally in relation to the adjacent components or modules 7. More specifically, these nozzles 11 can be placed centrally or substantially centrally in relation to the facing edges or edge corners of the two adjacent components or modules 7, which can be longitudinal or alternatively lateral edges.

The dimensions of the nozzles 11, in particular their height, can be adapted on the basis of the interior space of the housing 5, in particular between the components or modules 7 and the cover 53 of the housing 51.

As an alternative or in addition, one or more nozzles 11 can be intended to be placed facing a gap between at least one component or module 7 and a wall of the housing 51. In particular, this is a lateral wall of the housing 51 that faces a lateral face 73 or 75 of the component or module 7. Such nozzles 11 can be placed centrally in relation to an edge or an edge corner of the component or module 7, which can be a longitudinal or lateral edge, facing the wall of the housing 51. According to another example, such nozzles 11 can be placed facing a gap between a tip of the component or module 7 and the wall of the housing 51.

According to another variant or in addition, one or more nozzles 11 can be intended to be placed facing a gap between at least two facing tips of two adjacent components or modules 7.

When the components or modules 7 to be thermally regulated are positioned in multiple rows, one or more series of nozzles 11 can be associated with each row.

It can also be conceivable to place one or more nozzles 11 facing a gap between two rows of components or modules 7.

It could also be envisaged to place one or more nozzles 11 so as to project at least one jet of dielectric fluid at least partially onto a deflecting wall of the housing 5.

The deflecting wall of the housing 51 can in particular be placed facing at least one surface of one or more components or modules 7. One or more spraying nozzles 11 can be placed between one or more components or modules 7 and this deflecting wall. Such a deflecting wall makes it possible to deflect at least a portion of the jet toward a surface of one or more components or modules 7. This causes the jet to be dispersed over a surface of at least one component or module 7 that is larger than the surface of the deflecting wall intended to be wetted by the initial jet of dielectric fluid.

The deflecting wall is, for example, the cover of the housing 5 intended to be placed facing the upper faces 71 of the components or modules 7. According to another variant, the deflecting wall can be a lateral wall of the housing 51 that faces the first or second lateral faces 73, 75 of the components or modules 7.

The nozzles 11 can also be placed in staggered fashion so as to wet at least one surface of one or more components or modules 7.

Irrespective of the envisaged placement strategy for the nozzles 11, at least some nozzles 11 can be close enough to obtain an overlap of the jets of dielectric fluid F20 that are intended to be projected. By way of example, such an overlap can be at least 20%. This makes it possible to optimize the wetting of the components or modules 7 to be thermally regulated.

As regards the orientation of the nozzles 11, one or more nozzles 11 can be oriented such that their projecting orifice is placed facing the surface of one or more components or modules 7 to be wetted.

In a variant or in addition, one or more nozzles 11 can be oriented such that their projecting orifice is placed facing the possible deflecting wall of the housing 51 toward which the initial jet of dielectric fluid is to be projected. In this case, the projecting orifice of the nozzle 11 is situated opposite the component or module 7 to be thermally regulated.

In an alternative or in addition, at least some nozzles 11 can be placed such that their projecting orifice is at least partially oriented toward the component or module 7 to be wetted and toward a possible deflecting wall of the housing 51, such that a portion of the jet of dielectric fluid is projected onto a surface of the component or module 7 and another portion of the jet of dielectric fluid is projected toward such a deflecting wall, and then deflected so as to wet a larger surface of the component or module 7. These nozzles 11 can be placed between the component or module 7 and a lateral wall of the housing 51, for example.

Lastly, multiple nozzles 11 can be oriented, for example mirrored, so as to project complementary jets of dielectric fluid to optimize the wetting of at least one surface of one or more components or modules 7.

The nozzles are fluidically connected to at least one supply line 13. Advantageously, one or more nozzles 11 can be produced with a supply line 13, for example by overmolding. As an alternative, the nozzles 11 can be distinct from the supply line 13 and be fluidically connected at the distribution or connection points 14 of the supply line 13. In this case, the nozzles 11 can for example be metallic. The nozzles 11 can for example be screwed, clipped or else inserted, mounted by fitting.

The nozzles 11 can be intended to be supplied in series by a common supply line 13 of the dielectric fluid circuit 9. In a variant, at least some nozzles 11 can be supplied by bypass lines.

When there is a multiplicity of nozzles 11, they can be identical or different, have the same or a different number of projecting orifices, and have projecting orifices with the same or different areas of opening, for example of the same diameter or different diameters. The nozzles 11 can be placed in an identical or substantially identical orientation, or mirrored, or in variable orientations, in relation to the components or modules 7 or to a supply line 13 of the dielectric fluid circuit 9.

### Dielectric Fluid Collector

The collector 16, for its part, is configured to be placed so as to collect the dielectric fluid after the spraying operation. It has a recessed form for collecting the dielectric fluid, which flows for example along the walls of the components or modules 7 after the spraying operation. The dielectric fluid collected in the collector 16 is indicated by the arrow F30.

The collector 16 is also fluidically connected to the outlet port 4, so as to make it possible to discharge the dielectric fluid, as shown schematically by the arrows F40.

The collector 16 is situated opposite the one or more supply lines 13. In the example illustrated, it is placed between the components or modules 7 and the bottom wall 55 of the housing 51. This makes it possible to collect the dielectric fluid underneath the components or modules 7. In particular, the collector 16 extends facing the entire lower face of the components or modules 7.

Advantageously, the collector 16 can be integrated in the housing 51, in particular by overmolding. This can advantageously be done with a collector 16 made of a composite plastics material, which is in particular heat-resistant.

As an alternative, the collector 16 could be produced separately from the housing 51. In this case, it can be assembled in the housing 51 for example by clipping or screwing.

Furthermore, the collector 16 extends for example mainly along a longitudinal axis L.

The collector 16 also has at least one separating rib 18. Such a rib 18 can in particular be produced easily in the case of a collector 16 made of plastic, and preferably of composite plastics material.

The or each separating rib 18 is configured to extend between at least two components or modules 7. It extends parallel to two facing lateral faces 73 of the two components or modules 7.

The rib 18 extends continuously, in particular over the entire length of a component or module 7. In a variant, such a rib could extend over the entire width of a component or module 7.

In addition, the rib 18 extends along an axis T transverse to the longitudinal axis L, vertically with reference to the orientation of the elements in FIG. 1. More specifically, it extends perpendicularly or substantially perpendicularly to the bottom wall 55 of the housing 51.

This rib 18 can extend over a predefined height, in order to not disrupt the runoff of the dielectric fluid between the components or modules 7 after the spraying operation. This height is, for example, less than half the height of a component or module 7.

Such a rib 18 is advantageously configured to define at least two distinct dielectric fluid collecting cavities or compartments 20 on either side of this rib 18. In other words, the collector 16 defines the at least two dielectric fluid collecting compartments 20 on either side of the rib 18. The collecting compartments 20 define recessed internal volumes or spaces in the collector 16.

The rib 18 forms an obstacle preventing the dielectric fluid from moving from one collecting compartment 20 to the next. This maintains a minimum amount of dielectric fluid in each collecting compartment 20.

As a result, the rib 18 allows the dielectric fluid flowing along the components or modules 7 to be collected in each of the compartments 20. This avoids non-uniform accumulation of the dielectric fluid, for example on one side of the thermal regulation device 3. This is all the more necessary in the case of a considerable inclination in relation to the horizontal of the thermal regulation unit 1 or of the vehicle fitted with such a unit 1.

Such a rib 18 can also have a function of holding the components or modules 7 in position in the housing 51.

Advantageously, the collector 16 has more than one rib 18 and therefore more than two collecting compartments 20.

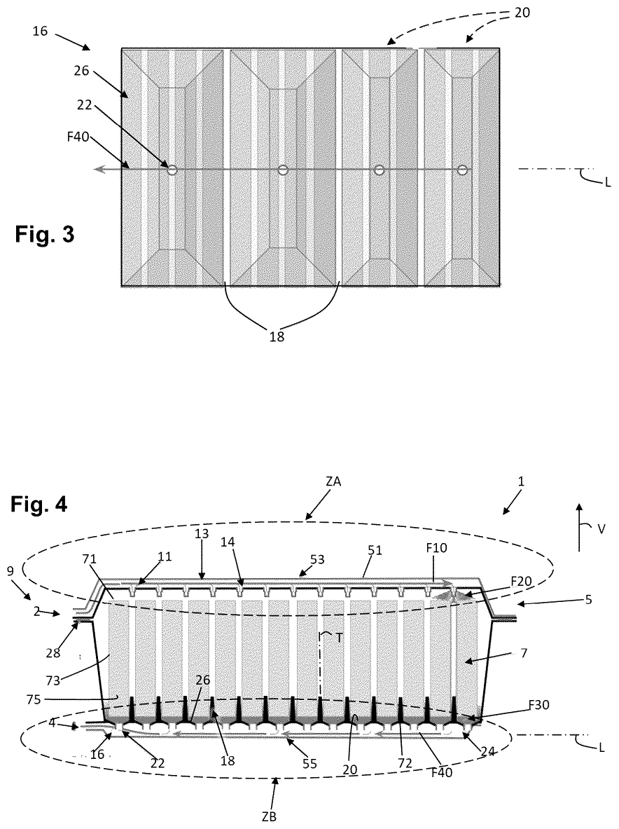

According to a first embodiment shown in FIGS. 1 and 3, the collector 16 has at least two ribs, for example three ribs 18. This makes it possible to define four collecting compartments 20 in this example. Of course, these numbers are not limiting.

The ribs 18 can be spaced by a predefined interval. This interval can be constant or non-constant.

According to a second embodiment shown in FIG. 4, the collector 16 has a plurality of ribs 18, and in particular one rib 18 between each pair of components or modules 7.

The ribs 18 are spaced by a predefined and constant interval corresponding to the space between two facing lateral faces 73 of the components or modules 7.

This second embodiment makes it possible to increase the number of collecting compartments 20 and to make the collection of the dielectric fluid all the more uniform, in particular before the discharging operation.

Furthermore, the collector 16 comprises a predefined number of dielectric fluid discharging orifices 22.

The discharging orifices 22 can be formed on a face of the collector 16 that is referred to as the lower face and is intended to be placed facing the bottom wall 55 of the housing 51.

The number of discharging orifices 22 can be adapted depending on the number of collecting compartments 20 defined on either side of a rib 18. For example, at least one discharging orifice 22 can be formed in the collector 16 in fluidic communication with each collecting compartment 20. As a result, it is possible to provide at least as many discharging orifices 22 as there are collecting compartments 20.

These discharging orifices 22 are intended to be fluidically connected to the dielectric fluid outlet port 4.

In particular, the discharging orifices 22 can lead into at least one discharge line 24.

The discharge line 26 is, for example, formed between the collector 16 and the housing 51, more specifically a wall of the housing, such as the bottom wall 55, positioned facing the discharging orifices.

The outlet port 4 can also lead into this discharge line 24. As a result, the dielectric fluid collected in each compartment 20 and flowing through at least one of the discharging orifices 22 flows into said discharge line 24, to be discharged through the outlet port 4, for example by being drawn in by a pump.

A multiplicity of discharging orifices 22 in fluidic communication with a plurality of collecting compartments 20 (FIG. 4) makes it possible to facilitate the drawing-in by the pump.

Moreover, in order to promote the flow of the dielectric fluid toward a discharging orifice 22, the collector 16 advantageously has at least one slope 26. Such a slope 26 descends toward the discharging orifice 22.

According to the embodiments illustrated in FIGS. 1 and 4, this slope 26 is inclined in relation to the bottom wall 55 of the housing 51.

The slope 26 is intended to be inclined in relation to the horizontal, for example once the thermal regulation device 3, and more generally the thermal regulation unit 1, is installed in a vehicle.

The slope 26 forms a non-zero angle of inclination in relation to the bottom wall 55 of the housing 51, or in relation to the horizontal. The angle of inclination is less than 90°, for example is around 45°.

The or at least one slope 26 can extend from a rib 18 to at least one discharging orifice.

Multiple slopes 26 can be provided. They can have the same angle or different angles. The dimensions of the slopes 26, in particular their lengths, can be identical or different.

According to a particular example, the collector 16 can be designed with at least two slopes 26 extending on either side of a rib 18, the slopes 26 descending to a respective discharging orifice 22. The collector 16 thus has a non-flat shape, for example wavy or sawtooth shape. This in particular gives the collector 16 one or more portions of frustoconical overall shape, as can be seen more clearly in FIG. 3.

The slope 26 can have the same angle of inclination on each side of the rib 18. It is also conceivable for the slope 26 to differ on each side of the rib 18.

The collector 16 can have slopes 26 which descend toward each discharging orifice 22. The number of slopes 26 can thus vary on the basis of the number of ribs 18 and discharging orifices 22.

The collector 16 can also have at least one descending slope 26 extending from an end wall to a discharging orifice 22.

The collector 16 can possibly be joined to the inlet port and/or at least one supply line 13. Leaktightness can be realized by welding or adhesive bonding or by means of at least one sealing member 28, such as a gasket.

In the description above, the thermal regulation device 3 is placed in a housing 51 that receives modules 7, it being possible for each module 7 to comprise one or more electric and/or electronic components. Each module 7 can also correspond to such a component or a battery cell, for example. The description can also be applied to a thermal regulation device 3 placed within multiple housings or modules of a larger unit, each module or housing receiving multiple components or battery cells, for example.

The dielectric fluid collector 16 of the thermal regulation device 3 as described above thus makes it possible to collect dielectric fluid after the spraying operation, at multiple points by virtue of the separating ribs 18, for example in a lower part of the housing. The dielectric fluid is collected uniformly, without accumulation or retention at a given point, irrespective of the inclination of the unit 1 or of a vehicle fitted with such a unit 1. The dielectric fluid collected can then be discharged, for example by being drawn in by a pump, without risking damage to the pump or needing to increase the power of the pump.

What is claimed is:

1. A device for thermal regulation of at least two electronic and/or electric components, comprising:
a dielectric fluid circuit including at least one supply line, and
a predefined number of dielectric fluid spraying nozzles fluidically connected to said at least one supply line and configured to be placed so as to wet at least one surface of at least one electronic and/or electric component of the at least two electronic and/or electric components,
wherein said device includes at least one dielectric fluid collector configured to be placed so as to collect the dielectric fluid after the spraying operation, said collector having at least one separating rib configured to extend between at least two electronic and/or electric components.

2. The device as claimed in claim 1, wherein said at least one separating rib is configured to define at least two distinct dielectric fluid collecting compartments on either side of said rib.

3. The device as claimed in claim 1, wherein said at least one dielectric fluid collector extends mainly along a longitudinal axis and wherein said at least one separating rib extends along an axis transverse to the longitudinal axis, and is configured to extend parallel to two facing lateral faces of said at least two electronic and/or electric components.

4. The device as claimed in claim 1, wherein said at least one dielectric fluid collector has a plurality of ribs spaced by a predefined interval and configured to extend between each pair of electronic and/or electric components of said at least two electronic and/or electric components.

5. The device as claimed in claim 1, wherein said at least one dielectric fluid collector is situated opposite said at least one supply line.

6. The device as claimed in claim 1, wherein said at least one dielectric fluid collector includes a predefined number of dielectric fluid discharging orifices.

7. The device as claimed in claim 6, wherein said at least one dielectric fluid collector has at least one descending slope inclined in relation to the horizontal and descending toward at least one discharging orifice of the predefined number of dielectric fluid discharging orifices.

8. The device as claimed in claim 7, wherein the at least one descending slope extends from said at least one separating rib to said at least one discharging orifice of the predefined number of dielectric fluid discharging orifices.

9. The device as claimed in claim 1, wherein at least one of the following elements: said at least one supply line, said at least one dielectric fluid collector and said at least one separating rib, is made from a composite plastics material.

10. A thermal regulation unit comprising at least two electronic and/or electric components and at least one thermal regulation device including:
a dielectric fluid circuit including at least one supply line,
a predefined number of dielectric fluid spraying nozzles fluidically connected to said at least one supply line and placed so as to wet at least one surface of at least one component of the at least two electronic and/or electric components, and
at least one dielectric fluid collector placed so as to collect the dielectric fluid after the spraying operation, said at least one dielectric fluid collector having at least one separating rib extending between at least two electronic and/or electric components.

11. The unit as claimed in claim 10, having a housing that receives at least two electronic and/or electric components, and wherein:
the housing has a cover that closes the housing, and a bottom wall situated opposite the cover,
said at least one at least one supply line is placed between said at least two electronic and/or electric components and the cover, and
said at least one dielectric fluid collector is placed between said at least two electronic and/or electric components and the bottom wall.
